(19) United States
(12) Patent Application Publication
(10) Pub. No.: US 2024/0129171 A1
(43) Pub. Date: Apr. 18, 2024

(54) SIGNAL TRANSMISSION DEVICE, SIGNAL TRANSMISSION METHOD AND COMMUNICATION SYSTEM

(71) Applicant: AcLeap Power Inc., Taipei City (TW)

(72) Inventors: Lishen Zhou, Shanghai (CN); Qixue Yu, Shanghai (CN); Qin Sun, Shanghai (CN)

(21) Appl. No.: 18/488,257

(22) Filed: Oct. 17, 2023

(30) Foreign Application Priority Data
Oct. 17, 2022 (CN) 202211268989.5

(51) Int. Cl. H04L 25/49; H03K 4/08; H03K 5/24

(52) U.S. Cl. CPC H04L 25/4902; H03K 4/08; H03K 5/24

(57) ABSTRACT

Embodiments of the present disclosure relate to signal transmission device, signal transmission method and communication system. The signal transmission device includes: a digital-to-analog converter configured to convert digital signals to analog signals; a modulator configured to modulate the analog signals to generate modulated pulse signals; and a transmitter configured to transmit, based on the modulated pulse signals, output pulse signals to a receiver, wherein the transmitter is configured to have no common ground with the receiver. In the solution in accordance with embodiments of the present disclosure, the high resolution can also be maintained under high speed data transmission, so as to overcome the conflicts between the resolution and the transmission frequency of the digital signal transmission in the existing schemes.

### CROSS-REFERENCE TO RELATED APPLICATIONS

This application claims priority to Chinese Patent Application No. 202211268989.5, filed on Oct. 17, 2022, and titled “SIGNAL TRANSMISSION DEVICE, SIGNAL TRANSMISSION METHOD AND COMMUNICATION SYSTEM”, which is hereby incorporated by reference in its entirety.

### BACKGROUND

The present disclosure relates to the field of communications, and more specifically, to signal transmission device, signal transmission method and communication system.

In some digital control or management systems, data transmission may occasionally be required between two isolated sides (i.e., two non-common-ground sides). One solution is by communication protocol such as Bluetooth, Wi-Fi etc. However, the high speed transmission requirement is usually unsatisfied in this solution. The other is direct high frequency signal transmission.

Current digital signal processing (DSP) chips and microcontroller units (MCU) usually include a pulse width modulation (PWM) module. The PWM module is often used to perform PWM modulation and further fulfill the digital signal transmission in digital systems. However, the period of the PWM signals in the digital system is decided by the size of the value of the cycle register. A greater bit number indicates a bigger theoretical numerical value. The actual value is associated with the desired period. If data are transmitted at a high PWM frequency, the value of the cycle register needs to be small. As the value of the cycle register decreases, the resolution (also known as precision) goes down. Thus, the original resolution could not be maintained when the data are transmitted at high-speed PWM frequency. An improved solution is in need to keep a relatively high resolution under high-speed data transmission.

### BRIEF DESCRIPTION

Embodiments of the present disclosure provide a signal transmission device to at least solve one of the above and other potential problems in the prior art.

In accordance with one aspect of the present disclosure, there is provided a signal transmission device, including: a digital-to-analog converter configured to convert digital signals to analog signals; a modulator configured to modulate the analog signals to generate modulated pulse signals; and a transmitter configured to transmit, based on the modulated pulse signals, output pulse signals to a receiver, wherein the transmitter is configured to have no common ground with the receiver. In the above embodiments, the analog signals are modulated by the modulator to generate the modulated pulse signals in the analog fashion. Because the frequency of the analog modulated signal is irrelevant of the precision of data transmission, the high resolution can also be maintained under high speed data transmission. The conflicts between the resolution and the transmission frequency of the data signal transmission in the existing solutions are accordingly overcome.

In some embodiments, the modulator is a pulse width modulator including: a periodic signal generator configured to generate periodic signals; and a comparator configured to compare the analog signals with the periodic signals and generate modulated pulse signals based on results of comparison. In the above embodiments, the pulse width modulator includes a periodic signal generator, which can modulate the analog signals in a simple and reliable way. The modulation process has no resolution loss since the comparison is made between two analog parameters (i.e., output of DAC and sawtooth or triangular wave). Accordingly, the transmission precision is associated with the precision of DAC alone, but the DAC precision is concerned with its bit number, i.e., unaffected by the transmission frequency.

In some embodiments, the periodic signal generator includes a triangular or sawtooth wave signal generator configured to generate triangular or sawtooth wave signals; and the comparator is configured to compare the analog signals with the triangular or sawtooth wave signals and generate the modulated pulse signals based on a result of comparison. In the above embodiments, the analog signals can be reliably modulated by the triangular or sawtooth wave signal generator via a simple structure.

In some embodiments, the transmitter includes an optical transmitter configured to convert the modulated pulse signals to optical pulse signals, so as to transmit to the receiver the optical pulse signals. In the above embodiments, reliable data transmission is implemented between the signal transmission device and the signal receiving device by the optical transmitter in a cost-effective and convenient way, where the signal transmission device and the signal receiving device have no common ground therebetween.

In some embodiments, the transmitter includes a transmitting antenna configured to transmit the pulse signals in the form of radio waves. In the above embodiments, reliable data transmission is implemented between the signal transmission device and the signal receiving device by the transmitting antenna in a convenient way.

In some embodiments, the first controller is configured to convert input signals to first digital signals and compute the first digital signals to generate the digital signals. In the above embodiments, the first controller converts input signals to first digital signals and computes the first digital signals, to obtain the desired digital signals for subsequent processing or control.

In some embodiments, the first controller includes the digital-to-analog converter or the digital-to-analog converter is independent of the first controller. In the above embodiments, the first controller may include the digital-to-analog converter. In other words, the digital-to-analog converter is positioned within the first controller, i.e., being a composite of the first controller. In this way, the built-in D/A converter of the DSP can be fully utilized. No separate D/A converters are added and the costs are also saved. Besides, if the DAC inside the DSP could not meet the requirement in scenarios with higher precision demand, an external DAC chip may also be added for conversion with higher precision.

In accordance with another aspect of the embodiments of the present disclosure, there is provided a signal transmission method, including: converting digital signals to analog signals; modulating the analog signals to generate modulated pulse signals; and transmitting, by a transmitter, to a receiver output pulse signals based on the modulated pulse signals, wherein the transmitter is configured to have no common ground with the receiver. In the above embodiments, the frequency of the modulation signals for modulating the analog signals is not concerned with the frequency of data transmission, so the conflicts between the resolution and the transmission frequency of the digital signal transmission in the existing schemes are overcome.

In some embodiments, modulating the analog signals to generate modulated pulse signals includes: generating periodic wave signals; and comparing the analog signals with the periodic signals and generating the modulated pulse signals based on a result of comparison.

In the above embodiments, by producing the periodic wave signals, the analog signals are modulated in a simple and reliable way. As the analog signals are continuous, the modulation process suffers no resolution loss. Hence, the demand is still met under high speed transmission.

In some embodiments, generating periodic wave signals includes: generating triangular or sawtooth wave signals; and comparing the analog signals with the periodic signals and generating the modulated pulse signals based on a result of comparison includes: comparing the analog signals with the triangular or sawtooth wave signals and generating the modulated pulse signals based on a result of comparison. In the above embodiments, the triangular or sawtooth signals are generated by the triangular wave or sawtooth generator, so as to reliably modulate the analog signals with a simple structure.

In some embodiments, transmitting to a receiver output pulse signals based on the modulated pulse signals includes: transmitting the output pulse signals by radio waves. In the above embodiments, reliable data transmission is implemented between the signal transmission device and the signal receiving device by the transmitting antenna in a convenient way, where the signal transmission device and the signal receiving device do not have common ground.

In some embodiments, the method also includes: converting input signals to first digital signals and computing the first digital signals to generate the digital signals. In the above embodiments, input signals are converted to first digital signals and the first digital signals are computed, to obtain the desired digital signals for subsequent processing or control.

In some embodiments, transmitting, by a transmitter, to a receiver output pulse signals based on the modulated pulse signals includes: converting the modulated pulse signals to optical pulse signals, so as to transmit to the receiver the optical pulse signals. In the above embodiments, when the output pulse signals are transmitted by the optical transmitter, data can be reliably transmitted between the signal transmission device and the signal receiving device, where the signal transmission device and the signal receiving device do not have common ground.

In accordance with another aspect of the embodiments of the present disclosure, there is provided a communication system, comprising the signal transmission device according to any of the claims; and a signal receiving device having no common ground with the signal transmission device, wherein the signal receiving device includes: a receiver configured to receive the output pulse signals and generate electric pulse signals based on the output pulse signals; and a demodulating unit configured to demodulate the digital signals from the electric pulse signals.

In the above embodiments, the communication system includes the above signal transmission device. The modulator modulates the analog signals with modulation signals, outputs the modulated pulse signals and transmits the same. The modulation signals are analog modulated signal whose frequency is irrelevant of the precision of data transmission. As such, the conflicts between the resolution and the transmission frequency of the digital signal transmission in the existing solutions are overcome.

In some embodiments, the output pulse signals include optical pulse signals, and the receiver includes an optical receiver configured to receive the optical pulse signals and convert the optical pulse signals to the electric pulse signals. In the above embodiments, the receiver includes an optical receiver, which receives the optical pulse signals and converts the optical pulse signals to the electric pulse signals for subsequent processing.

In some embodiments, the output pulse signals include radio wave signals, and the receiver includes a receiving antenna configured to receive the radio wave signals and convert the radio wave signals into the electric pulse signals. In the above embodiments, the receiving antenna receives the radio wave signals and converts the radio wave signals into the electric pulse signals, to implement the data transmission at low costs.

Through the following description, the defect, i.e., the conflicts between the resolution and the transmission frequency of the digital signal transmission in the existing schemes, can be overcome at low costs through the technical solution in accordance with embodiments of the present disclosure.

The brief description is to introduce a selection of concepts in a simplified form that are further described below in the detailed description. This brief description is not intended to identify key features or essential features of the present disclosure, nor is it intended to be used to limit the scope of the present disclosure.

### BRIEF DESCRIPTION OF THE DRAWINGS

FIG. 1 illustrates a schematic diagram of a communication system in accordance with some example embodiments of the present disclosure;

FIG. 2 illustrates a block schematic diagram of the signal transmission device in accordance with some example embodiments of the present disclosure;

FIG. 3 illustrates a schematic diagram of the PWM modulator in accordance with some example embodiments of the present disclosure;

FIG. 4 illustrates a waveform graph of the PWM modulator in accordance with some example embodiments of the present disclosure;

FIG. 5 illustrates a further waveform graph of the PWM modulator in accordance with some example embodiments of the present disclosure; and

FIG. 6 a flowchart of the signal transmission method in accordance with some example embodiments of the present disclosure.

In each drawing, same or corresponding reference signs indicate same or corresponding composites.

### DETAILED DESCRIPTION

Principles of the present disclosure are now explained with reference to various example embodiments shown in the drawings. It should be appreciated that description of those embodiments is merely to enable those skilled in the art to better understand and further implement the present disclosure and is not intended for limiting the scope disclosed herein in any manners. It should be noted similar or same reference signs can be used in the drawings where feasible, and similar or same reference signs can represent similar or same functions. Those skilled in the art will easily understand from the following description that alternative embodiments of the structure and/or method described in the text can be adopted without deviating from the principles of the present disclosure described herein

As used herein, the term “includes” or “comprises” and its variants are to be read as open-ended terms that mean “includes, but is not limited to.” Unless the context clearly indicates otherwise, the term “or” is to be read as “and/or”. The term “based on” is to be read as “based at least in part on.” The terms “one example embodiment” and “one embodiment” are to be read as “at least one example embodiment.” The term “a further embodiment” is to be read as “at least a further embodiment.” The terms “first”, “second” and so on can refer to same of different objects.

As stated above, two isolated sides in need of data communication, such as two circuits without common ground, could not be linked directly through wires for data transmission. Such data transmission is usually performed via Bluetooth, Wi-Fi or digital pulse width modulation and the like.

In some related schemes, data transmission is more convenient and much faster by modulated signals than Bluetooth and Wi-Fi. As such, digital signals may be modulated directly by a PWM module in DSP chip or MCU and further transmitted. The modulation is in digital form. The modulated signals may be sent to a receiving side and the modulation frequency is the frequency at which the data are sent.

However, period of the PWM signal in a digital system is often determined by a cycle register in the DSP chip or MCU. The cycle register may be used for storing the number of counts made by a timer. If the data are transmitted at a high PWM frequency, the period is required to be quite small, so is the value of the cycle register. As the value of the cycle register decreases, the resolution goes down.

The value in the PWM cycle register indicates the count for system clock period, and the period of PWM is decided by the value contained in the cycle register. Each bit in the cycle register represents one system clock period. The PWM period extends as the value grows. In addition, if the cycle register includes more bits, it means that a greater value can be stored in it. Data resolution is a reciprocal of the stored value. Thus, a register with more bits is desired under situations with high precision requirement.

The cycle register in DSP or MCU usually has 16 bits and is capable of storing 16 power of 2, i.e., 65536. However, even if the register has a 16-bit resolution, it could not maintain its original resolution at a higher PWM frequency. In case of an extremely high PWM frequency, the PWM period is short, i.e., the value of the cycle register is required to be small. In other words, even if the register contains many bits, they could not be fully utilized and part of them remains idle. The bits thus are not exploited to their best. Hence, the resolution is low if the PWM frequency is extremely high.

For example, the system clock frequency is 100 MHz, indicating a system clock period of 10 ns. In such case, for the 16-bit cycle register, the longest clock is 10 ns multiplied by 65536, and the corresponding frequency is about 1.5 kHz. Digital signals generated from the computation of the first digital signal may be put in a duty cycle register, which duty cycle register corresponds to the cycle register. In other words, the cycle register determines the length of a period. When the period is determined, the value of the register is also decided (i.e., a fixed value). The duty cycle register determines the length of a high-level period and this length varies with the size of the digital signal. The duty cycle increases as the data value becomes greater. When the data in the duty cycle register is zero, the duty cycle is zero; when the data in the duty cycle register is at maximum value (i.e., every bit is 1), the duty cycle is 1.

If a desired PWM frequency is 200 kHz, the cycle register will be set to 500, i.e., the maximum data to be stored in the register is 500 and the resolution is less than 9 bits (9 power of 2=512). For some applications, the resolution is so low that it is unacceptable. Thus, some related schemes often fail to overcome the conflicts between high resolution and high speed. An improved solution is accordingly in need to maintain a high resolution under high-speed data transmission.

Embodiments of the present disclosure propose an improved solution, in which a signal transmission device is provided. The signal transmission device includes a digital-to-analog converter, a modulator and a transmitter. The digital-to-analog converter may convert received digital signals to analog signals. The received digital signals may be any digital signals, e.g., digital signals produced from analog-to-digital conversion of analog digitals collected in real time, or signals resulted from additional digital computations of other digital signals. The modulator may modulate the analog signals to generate modulated pulse signals. The transmitter transmits and outputs the pulse signals to the receiver based on the modulated pulse signals, wherein the transmitter and the receiver do not have common ground. In this way, high resolution is also maintained when the data are transmitted at a high speed since the frequency of the analog modulated signals is unrelated to the resolution of data transmission. Therefore, the conflicts between resolution and transmission frequency of digital signal transmission in the existing schemes can be overcome.

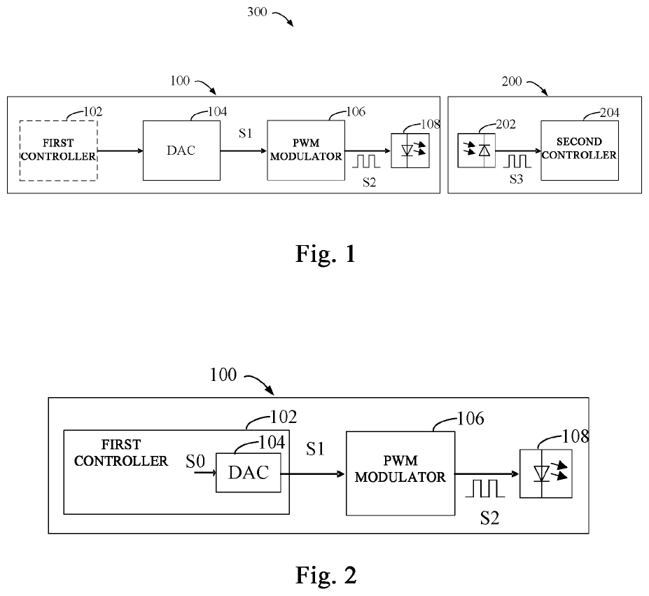

Embodiments of the present disclosure are to be described in details below with reference to the drawings. FIG. 1 illustrates a schematic diagram of a communication system 300 in accordance with some example embodiments of the present disclosure. In some embodiments, the communication system includes a signal transmission device 100 and a signal receiving device 200 according to FIG. 1. The signal transmission device 100 may include a DAC 104, a PWM modulator 106 and a transmitter 108. In some embodiments, the signal transmission device 100 also may include a first controller 102. In some embodiments, the first controller for example is first DSP/MCU. It is to be understood that the first controller also may be implemented by other devices with processing and control capacity (e.g., microcontroller). The specific implementations of the first controller are not restricted in the present disclosure.

In some embodiments, the first controller 102 may receive an input signal and convert the input signal into a digital signal. The received signal may be various, either an analog signal or a digital signal. In some embodiments, the first controller 102 may convert the input signal into a first digital signal and compute the first digital signal to generate a digital signal. The generated digital signal may be input to the DAC 104. The computation of the first digital signal may include performing a predetermined operation on the converted first digital signal, e.g., Proportion Integration Differentiation (PID) operation. It is to be appreciated that any operations may be performed on the first digital signal according to the actual needs and the present disclosure is not restricted in this regard.

Although the signal transmission device 100 may include the first controller 102 as illustrated in the above embodiments, embodiments of the present disclosure are not restricted to this. The first digital signal may be input to the DAC 104 directly or after a predetermined operation process for digital-to-analog conversion, depending on the actual requirements.

The DAC 104 may convert the received digital signal to an analog signal S1. The DAC 104 may be a digital-to-analog converter with suitable bits as required. The conversion precision increases as more bits are involved. Although resolution loss also exists in the digital-to-analog conversion, it is not concerned with the data transmission speed. In a situation where data are transmitted at high speed and high resolution rate, the DAC 104 with sufficient bits (e.g., 16 or more bits) is adopted. In general, the DAC 104 in DSP or MUC can meet the requirement.

The PWM modulator 106 may modulate the received analog signal S1, e.g., with analog modulated signals, to output a modulated pulse signal S2. In some embodiments, the transmitter 108 may include a transmitting antenna that may transmit pulse signals by radio waves. In some embodiments, the transmitter 108 may include an optical transmitter, which optical transmitter may convert the modulated pulse signal S2 into an optical pulse signal and transmit the optical pulse signal to the receiver.

In the above embodiments, the transmitter is illustrated by an example of optical transmitter and antenna. The transmitter of the present disclosure is not limited to this and instead may be any devices that can transmit pulse signals through radio waves (including optical waves).

The signal transmission device in accordance with some embodiments of the present disclosure is to be explained by an example of power supply control. The analog input signal for example may be an output voltage signal acquired from a voltage detection circuit. The output voltage signal acquired from the voltage detection circuit may be input to the first controller 102, which may convert the analog input signal into digital signal. The converted digital signal may be subject to a predetermined operation, such as Proportion Integration Differentiation PID operation. The obtained PID result (a numeric value) may be input to the DAC 104 for digital-to-analog conversion, so as to generate an analog signal S1. The analog signal S1 may be input to the modulator, e.g., PWM modulator 106, to generate through PWM modulation the modulated pulse signal S2. The pulse signal may be transmitted to a receiving device via the optical transmitter or the transmitting antenna. The receiving device may demodulate the PID result from the received pulse signal. The PID result may be transmitted to a driving circuit of a power device, to regulate ON and OFF time of the power device, so as to control the output voltage. In the above embodiments, the analog input signal received by the first controller 102 is demonstrated by an example of power supply control. Clearly, embodiments of the present disclosure are not restricted to this, and the analog input signal received by the first controller 102 may be various analog signal.

As shown in FIG. 1, the signal receiving device 200 may include a signal receiver 202 and a second controller 204, the second controller 204 for example being a second DSP/MCU. The receiver 202 may receive the pulse signal. The receiver 202 may include an optical receiver that receives an optical signal, converts the optical signal into an electric pulse signal S3 and transmits to the second controller 204. The receiver 202 also may be a receiving antenna, which receives the signal from the transmitting antenna, converts the received signal to the electric pulse signal S3 and transmits to the second controller 204. It is to be understood that the second controller also may be implemented by other devices with processing and control capacity (e.g., microcontroller). The specific implementations of the second controller are not restricted in the present disclosure.

The second controller 204 may include a demodulator that demodulates the digital signal from the electric pulse signal. The demodulated digital signal may be subject to predetermined subsequent processing or control as required.

FIG. 2 illustrates a block schematic diagram of the signal transmission device 100 in accordance with some example embodiments of the present disclosure. As shown, the signal transmission device 100 includes the first controller 102, the DAC 104, the PWM modulator 106 and the transmitter 108. The first controller 102 (such as first DSP or MCU) may include the digital-to-analog converter. In other words, the regular DSP or MCU contains the DAC 104, so the DAC 104 in the DSP or MCU may be directly employed for digital-to-analog conversion to save costs in some embodiments. According to FIG. 2, the digital signal S0 output from the first controller 102 is input to the DAC 104 for digital-to-analog conversion, to generate the analog signal S1. The analog signal S1 is input to the PWM modulator 106 for PWM modulation, so as to generate the pulse signal S2.

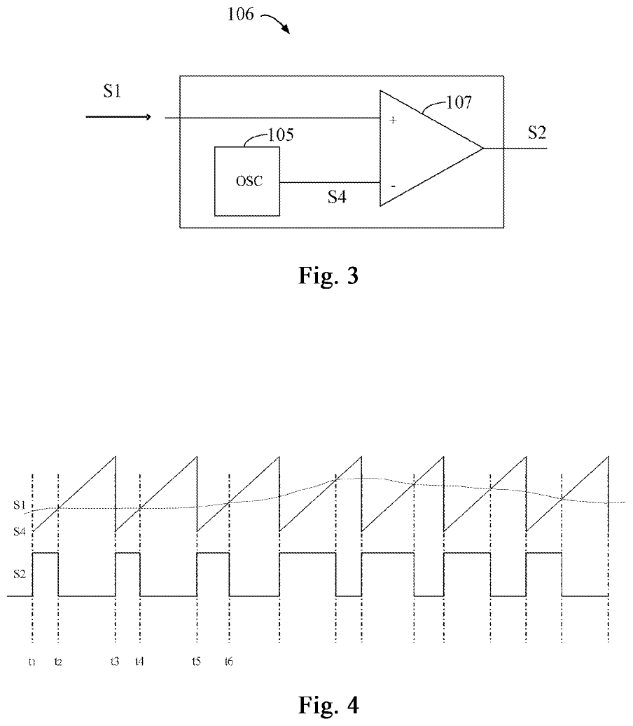

FIG. 3 illustrates a schematic diagram of the PWM modulator 106 in accordance with some example embodiments of the present disclosure. In some embodiments, the PWM modulator 106 may include: a periodic signal generator and a comparator 107. The periodic signal generator may produce periodic signals. In some embodiments, the periodic signal generator may be a triangular or sawtooth wave signal generator. As shown in FIG. 3, the PWM modulator 106 may include a triangular or sawtooth wave generator 105 and a comparator 107. The triangular or sawtooth wave generator 105 may produce triangular or sawtooth wave signals. The comparator 107 may compare the analog signal S1 with the triangular or sawtooth wave signal and output the modulated pulse signal S2 on the basis of the comparison result.

The triangular or sawtooth wave generator is provided here as an example for explaining the periodic signal generator. Embodiments of the present disclosure are not restricted to this. The periodic signal generator also may be other waveform generators.

In the above embodiments, the PWM modulation is taken as the example to explain how the digital signal is modulated. Embodiments of the present disclosure are not restricted to this. The modulation may be in other forms, such as pulse frequency modulation (short for PFM). In PFM, the frequency of the modulated signal varies with the amplitude of the input signal while the duty cycle remains unchanged. Specific implementations of the solution are not described in details here. Those skilled in the art may easily understand and implement the solution based on the teaching provided by the present application in view of the common knowledge.

FIG. 4 illustrates a waveform graph of the PWM modulator 106 in accordance with some example embodiments of the present disclosure. In FIG. 4, the digital signal S1 output by the DAC 104, the signal S2 output by the PWM modulator and the signal S4 output by the triangular or sawtooth wave generator (OSC) 105 are demonstrated in sawtooth wave.

During a period of time from t1 to t2, the signal S4 is smaller than the analog signal S1 converted and output by the DAC 104. Through the comparison by the comparator 107, a high-level pulse signal S2 is output. During a period of time from t2 to t3, the signal S4 is greater than the digital signal S1 output by the DAC 104. Subsequent to the comparison by the comparator 107, a low-level pulse signal S2 is output. Similarly, during the periods of time from t3 to t4 and from t4 to t5 and the periods following that, the comparator 107 outputs the corresponding modulated pulse signal S2 according to the comparison result between the signal S4 and the analog signal S1. The waveform illustrated here is exemplary and the solution of the present disclosure is not restricted to this. In the modulated pulse signal S2, a greater duty cycle of the high-level pulse in each period indicates a bigger value.

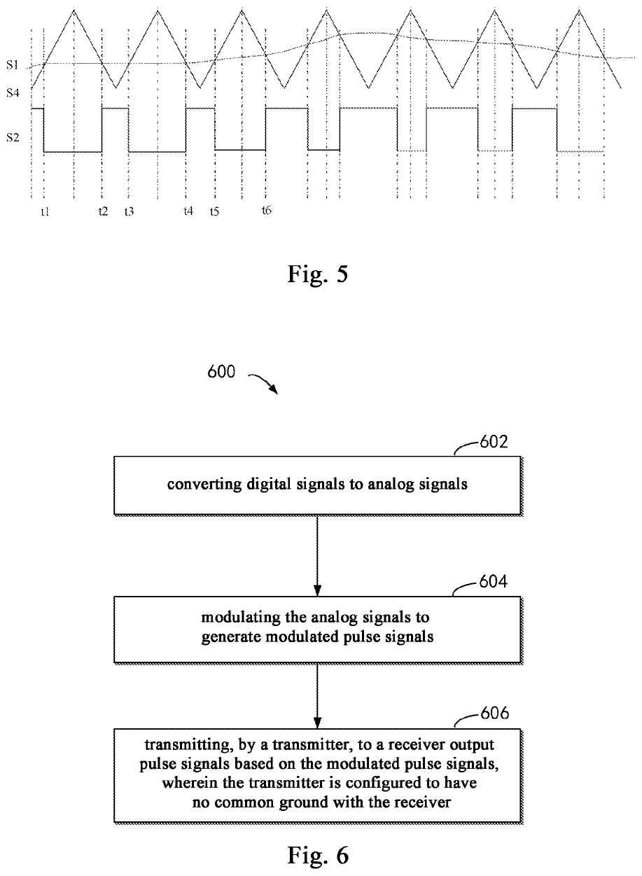

FIG. 5 illustrates a further waveform graph of the PWM modulator in accordance with some example embodiments of the present disclosure. In FIG. 5, a waveform resulted from modulating the analog signal S1 with the signal S4 (triangular wave as shown) generated by the triangular or sawtooth wave generator 105 is provided. The signal S4 is fed to a negative input end of the comparator 107 while the analog signal S1 is fed to a positive input end of the comparator 107 for comparison. When the analog signal S1 is greater than the signal S4, a high-level pulse signal 102 is output; otherwise, a low-level pulse signal S2 is output. The waveforms at respective time points t1 to t6 transform in a way similar to FIG. 4 and will not be repeated.

Sawtooth wave and triangular wave are provided as examples in FIGS. 4 and 5 to explain the present disclosure and the solution of the present disclosure is not limited to this.

FIG. 6 illustrates a flowchart of the signal transmission method in accordance with some example embodiments of the present disclosure. In FIG. 6, a signal transmission method 500 is demonstrated, which method is executed by the signal transmission device 100. The method includes:

The digital signals are converted into analog signals at 602. In some embodiments, the digital signals are converted into analog signals to facilitate subsequent analog modulation processing. The DAC 104 with suitable bit number may be employed according to the needs. The conversion precision increases as more bits are included in the DAC 104.

The analog signals are modulated to generate the modulated pulse signals S2 at 604. The duty cycle of the digital PWM-modulated signals is non-continuous while the duty cycle of the analog modulated signals can be made continuous. As the frequency of the analog modulated signals are irrelevant with the resolution of data transmission, the high resolution can also be maintained at high speed data transmission.

In some embodiments, modulating the analog signals to generate modulated pulse signals S2 may include: generating periodic wave signals, whose waveforms are not restricted here and any common periodic waveforms may be applied; comparing the analog signals S1 with the periodic signals, and generating the modulated pulse signals S2 based on a result of comparison.

In some embodiments, generating the periodic wave signals may include: generating triangular or sawtooth wave signals. Comparing the analog signals S1 with the periodic signals, and generating the modulated pulse signals S2 based on a result of comparison include: comparing the analog signals S1 with the triangular or sawtooth signals and generating the modulated pulse signals S2 based on a result of comparison.

At 606, output pulse signals are transmitted, by a transmitter, to a receiver at 606 based on the modulated pulse signals S2, wherein the transmitter is configured to have no common ground with the receiver. In this way, the resolution of the digital signal transmission is maintained while the data are transmitted at high speeds. This resolves the conflict issues between the resolution and the transmission frequency of the digital signal transmission.

In some embodiments, transmitting to a receiver output pulse signals based on the modulated pulse signals may include: transmitting the output pulse signals by radio waves.

In some embodiments, the input signals are converted into first digital signals, which first digital signals are further computed to generate the digital signals. Accordingly, a predetermined computation may be carried out on the first digital signals according to the needs, to obtain the desired signals for subsequent processing and control.

In some embodiments, transmitting, by a transmitter, to a receiver output pulse signals based on the modulated pulse signals S2 includes: converting the modulated pulse signals S2 to optical pulse signals, so as to transmit to the receiver the optical pulse signals.

As mentioned above, embodiments of the present disclosure are not limited to generating triangular or sawtooth wave signals by the triangular or sawtooth wave signal generator. Other waveform generators may also be employed.

In some embodiments of the present disclosure, the digital signals are converted to the analog signals S1 by the DAC 104 module. The analog signals S1 are then modulated by the analog modulator. The analog modulated signals are different from the digital PWM modulated signals introduced above in the existing schemes. The duty cycle of the digital PWM-modulated signals is non-continuous while the duty cycle of the analog modulated signals can be made continuous. The analog modulation has no concerns with the bit number of the register, so the low resolution issue under high speed does not exist. The solution in accordance with embodiments of the present disclosure is particularly suitable for data transmission between two circuits that are mutually isolated and have no common grounds therebetween.

In some embodiments of the present disclosure, a separate PWM modulator 106 is configured, which modulator has a modulation frequency irrelevant of the cycle register in the digital system. In such case the modulation frequency is unrelated to the resolution of the data transmission. Since the frequency of the analog modulated signal has no concern with the resolution of data transmission, the high resolution can be maintained in high speed data transmission situations. The conflicts between the resolution and the transmission frequency of the digital signal transmission are therefore overcome. The high resolution is maintained when data are transmitted at high speeds.

In some embodiments of the present disclosure, there is provided a communication system, comprising the signal transmission device 100 and the signal receiving device 200 according to the previous embodiments, where the signal receiving device 200 has no common ground with the signal transmission device 100. The signal receiving device 200 includes: a receiver 202 configured to receive output pulse signals and generate electric pulse signals S3 based on the output pulse signals; and a demodulator configured to demodulate the digital signals from the electric pulse signals S3.

In some embodiments, the output pulse signals include optical pulse signals, and the receiver 202 includes an optical receiver configured to receive the optical pulse signals and convert the optical pulse signals to the electric pulse signals S3.

In some embodiments, the output pulse signals include radio wave signals, and the receiver 202 includes a receiving antenna configured to receive the radio wave signals and convert the radio wave signals into the electric pulse signals S3.

In some embodiments of the present disclosure, the digital signals are converted into analog signals, the analog signals are modulated, and the modulated analog signals are transmitted to the receiver. Therefore, the high resolution is also maintained under high speed data transmission, and the conflicts between the resolution and the transmission frequency of the digital signal transmission in the existing schemes have been overcome.

In the above embodiments, the solutions according to the embodiments of the present disclosure have been explained with reference to the drawings. Embodiments of the present disclosure are not limited to the embodiments illustrated. Instead, various modifications may also be accepted.

Various embodiments of the present disclosure have been described above and the described embodiments are optional embodiments of the present disclosure. The above description is only exemplary rather than exhaustive and is not limited to the embodiments of the present disclosure. Although the claims of the present application are drafted for specific combinations of the features, it should be understood that the scope of the present disclosure also includes explicit or implicit features, or any novel features or any novel combinations of the features, no matter whether the features relate to the same solution in any claims or not. Applicant hereby states that new claims may be drafted for these features and/or combinations thereof in the examination procedure of the present application or any further applications derived from the present application.

The selection of terms in the text aims to best explain principles and actual applications of each embodiment and technical improvements made in the market by each embodiment, or enable those ordinary skilled in the art to understand embodiments of the present disclosure. Many modifications and alterations of the present disclosure are obvious for those skilled in the art. Any modifications, equivalent substitutions and improvements shall be included in the protection scope of the present disclosure as long as they are within the spirit and principle disclosed herein.

1. A signal transmission device, comprising:
a digital-to-analog converter configured to convert digital signals to analog signals;
a modulator configured to modulate the analog signals to generate modulated pulse signals; and
a transmitter configured to transmit, based on the modulated pulse signals, output pulse signals to a receiver, wherein the transmitter is configured to have no common ground with the receiver.

2. The signal transmission device of claim 1, wherein the modulator is a pulse width modulator comprising:
a periodic signal generator configured to generate periodic signals; and
a comparator configured to compare the analog signals with the periodic signals and generate the modulated pulse signals based on results of comparison.

3. The signal transmission device of claim 1, wherein the transmitter comprises an optical transmitter configured to convert the modulated pulse signals to optical pulse signals and transmit the optical pulse signals to the receiver.

4. The signal transmission device of claim 1, wherein the transmitter comprises a transmitting antenna configured to transmit the output pulse signals in a form of radio waves.

5. The signal transmission device of claim 1, further comprising:
a first controller configured to convert input signals to first digital signals and apply computation to the first digital signals to generate the digital signals.

6. The signal transmission device of claim 5, wherein the first controller comprises the digital-to-analog converter or the digital-to-analog converter is independent of the first controller.

7. The signal transmission device of claim 2, wherein the periodic signal generator comprises a triangular or sawtooth wave signal generator configured to generate triangular or sawtooth wave signals, respectively; and
the comparator is configured to compare the analog signals with the triangular or sawtooth wave signals and generate the modulated pulse signals based on the results of the comparison.

8. A signal transmission method, the method comprising:
converting digital signals to analog signals;
modulating the analog signals to generate modulated pulse signals; and
transmitting, by a transmitter to a receiver, output pulse signals based on the modulated pulse signals, wherein the transmitter is configured to have no common ground with the receiver.

9. The signal transmission method of claim 8, wherein modulating the analog signals to generate the modulated pulse signals comprises:
generating periodic wave signals; and
comparing the analog signals with the periodic wave signals and generating the modulated pulse signals based on results of comparison.

10. The signal transmission method of claim 9, wherein:
generating the periodic wave signals comprises:
generating triangular or sawtooth wave signals; and
comparing the analog signals with the periodic wave signals and generating the modulated pulse signals based on the results of the comparison comprises:
comparing the analog signals with the triangular or sawtooth wave signals and generating the modulated pulse signals based on the results of the comparison.

11. The signal transmission method of claim 8, wherein transmitting to the receiver, the output pulse signals based on the modulated pulse signals comprises:
transmitting the output pulse signals in a form of radio waves.

12. The signal transmission method of claim 8, further comprising:
converting input signals to first digital signals and computing the first digital signals to generate the digital signals.

13. The signal transmission method of claim 8, wherein transmitting, by the transmitter to the receiver, the output pulse signals based on the modulated pulse signals comprises:
converting the modulated pulse signals to optical pulse signals; and transmitting to transmit to the receiver, the optical pulse signals.

14. A communication system, comprising:
a signal transmission device, comprising:
a digital-to-analog converter configured to convert digital signals to analog signals;
a modulator configured to modulate the analog signals to generate modulated pulse signals; and
a transmitter configured to transmit, based on the modulated pulse signals, output pulse signals to a receiver; and
a signal receiving device having no common ground with the signal transmission device, the signal receiving device:
the receiver, wherein the receiver is configured to receive the output pulse signals and generate electric pulse signals based on the output pulse signals; and
a demodulator configured to demodulate the digital signals from the electric pulse signals.

15. The communication system of claim 14, wherein the output pulse signals comprise optical pulse signals, and the receiver comprises an optical receiver configured to receive the optical pulse signals and convert the optical pulse signals to the electric pulse signals.

16. The communication system of claim 14, wherein the output pulse signals comprise radio wave signals, and the receiver comprises a receiving antenna configured to receive the radio wave signals and convert the radio wave signals into the electric pulse signals.

17. The communication system of claim 14, wherein the modulator is a pulse width modulator comprising:
a periodic signal generator configured to generate periodic signals; and
a comparator configured to compare the analog signals with the periodic signals and generate the modulated pulse signals based on results of comparison.

18. The communication system of claim 17, wherein:
the periodic signal generator comprises a triangular or sawtooth wave signal generator configured to generate triangular or sawtooth wave signal, respectively, and
the comparator is configured to compare the analog signals with the triangular or sawtooth wave signals and generate the modulated pulse signals based on the results of the comparison.

19. The communication system of claim 14, wherein the signal transmission device further comprises:
a first controller configured to convert input signals to first digital signals and apply computation to the first digital signals to generate the digital signals.

20. The communication system of claim 19, wherein the first controller comprises the digital-to-analog converter or the digital-to-analog converter is independent of the first controller.
